(19) United States
(12) Patent Application Publication
(10) Pub. No.: US 2005/0227428 A1
(43) Pub. Date: Oct. 13, 2005

(54) Process for manufacturing mems

(76) Inventors: Ionescu Adrian Mihai, Lausanne (CH); Fluckiger Philippe, Bevaix (CH); Hibert Cyrille, St-Georges (CH); Fritschi Raphael, Lausanne (CH); Pott Vincent, Bramois (CH)

Correspondence Address: NIXON & VANDERHYE, PC, 901 NORTH GLEBE ROAD, 11TH FLOOR, ARLINGTON, VA, 22203, US

(21) Appl. No.: 10/507,920

(22) PCT Filed: Sep. 6, 2002
(86) PCT No.: PCT/CH02/00490

§ 371 Date: Oct. 19, 2004

(30) Foreign Application Priority Data
Mar. 20, 2002 (WO) PCT/CH02/00165

(51) Int. Cl. H01L 21/8238

(52) U.S. Cl. 438/222

(57) ABSTRACT

The invention concerns a process for manufacturing a Micro-Electro-Mechanical-System (MEMS) comprising the use of a sacrificial layer, the process being characterized by the fact that the sacrificial layer is made of silicon. The invention also concerns MEMS devices such as SG-MOSEFT, MEMS switches or MEMS tunable capacitors which may be obtained according to the previous cited process.

### FIELD OF THE INVENTION

This invention concerns a process for manufacturing a Micro-Electro-Mechanical-System (MEMS).

The invention also relates to some MEMS device architectures that may be obtained according to this process.

### STATE OF THE ART

SG-MOSFET:

Suspended or movable gate Metal Oxide Semiconductor Field Effect Transistors (SG-MOSFET) have been extensively reported in the literature and a number of device architectures have been disclosed for various applications.

SG-MOFSET devices are disclosed in the following documents:

Patent Literature:

| | | |
|---|---|---|
| [P-SG1]U.S. Pat. No. 6,204,544 | Louisiana | March 2001 |
| | State Univ. | |
| [P-SG2]U.S. Pat. No. 6,220,096 | Interscience, Inc. | April 2001 |
| [P-SG3]U.S. Pat. No. 5,874,675 | Interscience, Inc. | February 1999 |
| [P-SG4]U.S. Pat. No. 6,043,524 | Motorola, Inc. | March 2000 |
| [P-SG5]U.S. Pat. No. 5,903,038 | Motorola, Inc. | May 1999 |
| [P-SG6]U.S. Pat. No. 5,818,093 | Motorola, Inc. | October 1998 |
| [P-SG7]U.S. Pat. No. 5,600,065 | Motorola, Inc. | February 1997 |
| [P-SG8]U.S. Pat. No. 5,181,156 | Motorola, Inc. | January 1993 |
| [P-SG9]U.S. Pat. No. 5,786,235 | Siemens | July 1998 |
| [P-SG10] U.S. Pat. No. 5,627,397 | Nippondenso | May 1997 |
| | Co., Ltd. | |
| [P-SG11] U.S. Pat. No. 5,541,437 | Nippondenso | July 1996 |
| | Co., Ltd. | |
| [P-SG12] U.S. Pat. No. 4,906,586 | Cornell Research | March 1990 |
| | Foundation, Inc. | |
| [P-SG13] U.S. Pat. No. 4,812,888 | Cornell Research | March 1989 |
| | Foundation, Inc. | |

Non-Patent Literature:

[SG1] E. Hynes, P. Elebert, D. McAuliffe, et al., “The CAP-FET, a scaleable MEMS sensor technology on CMOS with programmable floating gate”, presented at International Electron Devices Meeting, 2001, pp. 917-920.

[SG2] D. M. Edmans, A. Gutierrez, C. Corneau, et al., “Micromachined accelerometer with a movable gate transistor sensing element”, Proceedings of SPIE, 3224, 1997, pp. 314-324.

[SG3] J. T. Suminto and W. H. Ko, “Pressure-sensitive insulated gate field-effect transistor (PSIGFET)”, Sensors and Actuators, A21-23, 1990, pp. 126-132.

[SG4] A. Yoshikawa, “Properties of a movable-gate-field-effect structure as an electromechanical sensor”, Journal of Acoustical Society of America, 64, 1978, pp. 725-730.

[SG5] H. C. Nathanson, W. E. Newell, R. A. Wickstrom, et al., “The resonant gate transistor”, IEEE Transactions on Electron Devices, 14(3), 1967, pp.117-133.

[SG6] A. M. Ionescu, “MEMS for Reconfigurable Wide-Band RF ICs”, Proceedings of SBMICRO 2001, Pirenopolis, Brasil, September 2001.

[SG7] V. Pott, A. M. Ionescu, R. Fritschi, et al., “The suspended-gate MOSFET (SG-MOSFET): a modeling outlook for the design of RF MEMS switches and tunable capacitors”, presented at International Semiconductor Conference (CAS '01), Sinaia, Romania, October 2001, pp.137-140.

[SG8] A. M. Ionescu, V. Pott, R. Fritschi, K. Banerjee, M. J. Declercq, Ph. Renaud, C. Hibert, Ph. Fluckiger and G.-A. Racine, “Modeling and design of a low-voltage SOI Suspended-Gate MOSFET (SG-MOSFET) with a metal-over-gate-architecture”, IEEE International Symposium on Quality Electronic Design (ISQED), San Jose, Calif., Mar. 18-21, 2002 (to appear).

RF MEMS Tunable Capacitor and Capacitive Switch

Tunable RF MEMS capacitors exploit the equilibrium between electrostatic and elastic forces applied to a movable conductive membrane and the related membrane displacement provides the tuning of the overall capacitor.

RF MEMS capacitive switches have an architecture very similar to a tunable capacitor, with the key difference that the metal membrane moves between two discrete states: up and down, acting on the capacitive coupling of a RF signal on an underneath metal layer that is covered by a thin insulator layer.

Consequently, a RF MEMS switch has two states ‘off’ and ‘on’, the late one obtained by pulling down the movable membrane with an applied voltage. MEMS switches have advantages in terms of low power consumption, low cost, linearity and potential compatibility with integrated circuits.

Capacitive RF MEMS switches and Tunable MEMS capacitors are disclosed in the following documents:

Patent Literature Related to RF MEMS Tunable Capacitors:

| | | |
|---|---|---|
| [P-TC1] WO 0,156,046 | Intel, Corp. | August 2001 |
| [P-TC2] WO 0,161,848 | Nokia Mobile | August 2001 |
| | Phones, Ltd | |
| [P-TC3] WO 0,145,127 | MCNC | July 2001 |
| [P-TC4] U.S. Pat. No. 5,959,516 | Rockwell Science | September 1999 |
| | Center LLC | |
| [P-TC5] U.S. Pat. No. 5,880,921 | Rockwell Science | March 1999 |
| | Center LLC | |

Non-Patent Literature Related to RF MEMS Tunable Capacitors:

[TC1] Young, D. J. and B. E. Boser, “A micromachined variable capacitor for monolithic low-noise VCO's”, presented at Solid-State Sensor and Actuator Workshop, Hilton Head Island, S.C., 1996, pp. 86-89.

[TC2] Young, D. J. and B. E. Boser, “A micromachine-based RF low-noise voltage-controlled oscillator”, presented at IEEE Custom Integrated Circuits Conference, 1997, pp. 431-434.

[TC3] Zou, J., C. Liu, J. Schutt-Aine, et al., “Development of a wide tuning range MEMS tunable capacitor for wireless communication systems”, presented at International Electron Devices Meeting, 2000, pp. 403-406.

[TC4] Zou, J. and C. Liu, “Development of a novel micro electromechanical tunable capacitor with a high tuning range”, presented at 58th Device Research Conference, 2000, pp. 111-112.

[TC5] Dec, A. and K. Suyama, “Micromachined electro-mechanically tunable capacitors and their applications to RF IC's”, IEEE Transactions on Microwave Theory and Techniques, 46 (12), 1998, pp. 2587-2596.

[TC6] Larson, L. E., R. H. Hackett, M. A. Melendes, et al., “Micromachined microwave actuator (MIMAC) technology: a new tuning approach for microwave integrated circuits”, presented at IEEE Microwave and Millimeter-Wave Monolithic Circuits Symposium, 1991, pp. 27-30.

[TC7] Yao, J. J., S. Park and J. DeNatale, “High tuning-ratio MEMS-based tunable capacitors for RF communications applications”, presented at Solid-State Sensor and Actuator Workshop, Hilton Head Island, S.C., 1998, pp.124-127.

[TC8] Hung, E. S. and S. D. Senturia, “Tunable capacitors with programmable capacitance-voltage characteristic”, presented at Solid-State Sensor and Actuator Workshop, Hilton Head Island, S.C., 1998, pp. 292-295.

[TC9] Park, J. Y., H.-T. Kim, Y. Kwon, et al., “A tunable millimeter-wave filter using coplanar waveguide and micromachined variable capacitors”, presented at 10th International Conference on Solid-State Sensors and Actuators (TRANSDUCERS '99), Sendai, Japan, 1999, pp. 1272-1275.

[TC10] Yoon, J.-B. and C. T.-C. Nguyen, “A high-Q tunable micromechanical capacitor with movable dielectric for RF applications”, presented at International Electron Devices Meeting, 2000, pp. 489-492.

[TC11] Fan, L., R. T. Chen, A. Nespola, et al., “Universal MEMS platforms for passive RF components: suspended inductors and variable capacitors”, presented at 11th Annual International Workshop on Micro Electro Mechanical Systems (MEMS '98), 1998, pp. 29-33.

[TC12] Wu, H. D., K. F. Harsh, R. S. Irwin, et al., “MEMS designed for tunable capacitors”, presented at IEEE MTT-S International Microwave Symposium, 1998, pp.127-129.

[TC13] Harsh, K. F., B. Su, W. Zhang, et al., “The realization and design considerations of a flip-chip integrated MEMS tunable capacitor”, Sensors and Actuators A, 80 (2), 2000, pp. 108-118.

[TC14] Feng, Z., W. Zhang, B. Su, et al., “Design and modeling of RF MEMS tunable capacitors using electro-thermal actuators”, presented at IEEE MTT-S International Microwave Symposium, 1999, pp.1507-1510.

Patent Literature Related to RF Switches:

| | | |
|---|---|---|
| [P-SW1] U.S. Pat. No. 5,619,061 | Texas | April 1997 |
| | Instruments, | |
| | Inc. | |
| [P-SW2] WO 0,031,819 | Raytheon, Co | June 2000 |
| [P-SW3] U.S. Pat. No. 6,307,519 | Hughes Electr., | October 2001 |
| | Corp.; Raytheon, | |
| | Co | |
| [P-SW4] U.S. Pat. No. 6,143,997 | Univ. Illinois, | November 2000 |
| | Urbana- | |
| | Champaign | |

Non-Patent Literature Related to RF Switches:

[SW1] S. Barker and G. M. Rebeiz, “Distributed MEMS true-time delay phase shifters and wide-band switches”, IEEE Transactions on Microwave Theory and Techniques, 46(11, Part 2), 1998, pp.1881-1890.

[SW2] C.-L. Dai, K. Yen and P.-Z. Chang, “Applied electrostatic parallelogram actuators for microwave switches using the standard CMOS process”, Journal of Micromechanics and Microengineering, 11 (6), 2001, pp. 697-702.

[SW3] C. Goldsmith, T.-H. Lin, B. Powers, et al., “Micromechanical membrane switches for microwave applications”, presented at IEEE MTT-S International Microwave Symposium, 1995, pp. 91-94.

[SW4] C. Goldsmith, J. Randall, S. Eshelman, et al., “Characteristics of micromachined switches at microwave frequencies”, presented at IEEE MTT-S International Microwave Symposium, 1996, pp.1141-1144.

[SW5] C. L. Goldsmith, Z. Yao, S. Eshelman, et al., “Performance of low-loss RF MEMS capacitive switches”, IEEE Microwave and Guided Wave Letters, 8(8), 1998, pp. 269-271.

[SW6] K. Grenier, B. P. Barber, V. Lubecke, et al., “Integrated RF MEMS for single chip radio”, presented at 11th International Conference on Solid-State Sensors and Actuators (TRANSDUCERS '01) and EUROSENSORS XV, Munich, Germany, 2001, pp. 1528-1531.

[SW7] D. Hyman and M. Mehregany, “Contact physics of gold microcontacts for MEMS switches”, presented at 44th IEEE Holm Conference on Electrical Contacts, 1998, pp. 133-140.

[SW8] D. Hyman, A. Schmitz, B. Warneke, et al., “GaAs-compatible surface-micromachined RF MEMS switches”, Electronics Letters, 35(3), 1999, pp. 224-226.

[SW9] D. Hyman and M. Mehregany, “Contact physics of gold microcontacts for MEMS switches”, IEEE Transactions on Components and Packaging Technologies, 22(3), 1999, pp. 357-364.

[SW10] J. Kim, W. Shen, L. Latorre, et al., “A micromechanical switch with electrostatically driven liquid-metal droplet”, presented at 11th International Conference on Solid-State Sensors and Actuators (TRANSDUCERS '01) and EUROSENSORS X, Munich, Germany, 2001, pp. 748-751.

[SW11] J. B. Muldavin and G. M. Rebeiz, “30 GHz tuned MEMS switches”, presented at IEEE MTT-S International Microwave Symposium, 1999, pp.1511-1514.

[SW12] J. B. Muldavin and G. M. Rebeiz, “High-isolation CPW MEMS shunt switches. 2. Design”, IEEE Transactions on Microwave Theory and Techniques, 48(6), 2000, pp.1053-1056.

[SW13] J. B. Muldavin and G. M. Rebeiz, “High-isolation CPW MEMS shunt switches. 1. Modeling”, IEEE Transactions on Microwave Theory and Techniques, 48(6), 2000, pp. 1045 -1052.

[SW14] J. B. Muldavin and G. M. Rebeiz, “High-isolation inductively-tuned X-band MEMS shunt switches”, IEEE MTT-S International Microwave Symposium, 1, 2000, pp.169-172.

[SW15] B. R. Norvell, R. J. Hancock, J. K. Smith, et al., “Micro electro mechanical switch (MEMS) technology applied to electronically scanned arrays for space based radar”, presented at IEEE Aerospace Conference, 1999, pp. 239-247.

[SW16] S. P. Pacheco, L. P. B. Katehi and C. T.-C. Nguyen, “Design of low actuation voltage RF MEMS switch”, presented at IEEE MTT-S International Microwave Symposium, 2000, pp. 165-168.

[SW17] J. Y. Park, G. H. Kim, K. W. Chung, et al., “Fully integrated micromachined capacitive switches for RF applications”, presented at IEEE MTT-S International Microwave Symposium, 2000, pp. 283-286.

[SW18] J. Y. Park, G. H. Kim, K. W. Chung, et al., “Electroplated RF MEMS capacitive switches”, presented at 13th Annual International Conference on Micro Electro Mechanical Systems (MEMS '00), 2000, pp. 639-644.

[SW19] J. Y. Park, K. Kang, N. Kang, et al., “A 3-voltage actuated micromachined RF switch for telecommunications applications”, presented at 11th International Conference on Solid-State Sensors and Actuators (TRANSDUCERS '01) and EUROSENSORS XV, Munich, Germany, 2001, pp. 1540-1543.

[SW20] K. E. Petersen, “Micromechanical membrane switches on silicon”, IBM Journal of Research and Development, 23(4), 1979, pp. 376-385.

[SW21] F. Plötz, S. Michaelis, G. Fattinger, et al., “Performance and dynamics of a RF MEMS switch”, presented at 11th International Conference on Solid-State Sensors and Actuators (TRANSDUCERS '01) and EUROSENSORS XV, Munich, Germany, 2001, pp. 1560-1563.

[SW22] J. Rizk, G.-L. Tan, J. B. Muldavin, et al., “High-isolation W-band MEMS switches”, IEEE Microwave and Wireless Components Letters, 11(1), 2001, pp. 10-12.

[SW23] I. Schiele and B. Hillerich, “Comparison of lateral and vertical switches for application as microrelays”, Journal of Micromechanics and Microengineering, 9(2), 1999, pp. 146-150.

[SW24] S.-C. Shen and M. Feng, “Low actuation voltage RF MEMS switches with signal frequencies from 0.25 GHz to 40 GHz”, presented at International Electron Devices Meeting, 1999, pp. 689-692.

[SW25] J. K. Smith, F. W. Hopwood and K. A. Leahy, “MEM switch technology in radar”, presented at IEEE International Radar Conference, 2000, pp. 193-198.

[SW26] K. Suzuki and A. Pauly, “Theoretical analysis of the tilting effect in silicon micro-switches”, presented at 11th International Conference on Solid-State Sensors and Actuators (TRANSDUCERS '01) and EUROSENSORS XV, Munich, Germany, 2001, pp. 244-247.

[SW27] H. A. C. Tilmans, H. Ziad, H. Jansen, et al., “Wafer-level packaged RF-MEMS switches fabricated in a CMOS fab”, presented at International Electron Devices Meeting, 2001, pp. 921-924.

[SW28] M. Ulm, T. Walter, R. Mueller-Fiedler, et al., “K-band capacitive MEMS-switches”, Topical Meeting on Silicon Monolithic Integrated Circuits in RF Systems, 2000, pp. 119-122.

[SW29] M. Ulm, M. Reimann, T. Walter, et al., “Scalability of capacitive RF MEMS switches”, presented at 11th International Conference on Solid-State Sensors and Actuators (TRANSDUCERS '01) and EUROSENSORS XV, Munich, Germany, 2001, pp. 1536-1539.

[SW30] J. J. Yao and M. F. Chang, “A surface micromachined miniature switch for telecommunications applications with signal frequencies from DC up to 4 GHz”, presented at 8th International Conference on Solid-State Sensors and Actuators (TRANSDUCERS '95), Stockholm, Sweden, 1995, pp. 384-387.

[SW31] Z. J. Yao, S. Chen, S. Eshelman, et al., “Micromachined low-loss microwave switches”, Journal of Microelectromechanical Systems, 8(2), 1999, pp. 129-134.

[SW32] P. M. Zavracky, S. Majumder and N. E. McGruer, “Micromechanical switches fabricated using nickel surface micromachining”, Journal of Microelectromechanical Systems, 6(1), 1997, pp. 3-9.

None of the types of inventions or publications referred hereto uses architectures with metal-over-gate SG-MOSFET, Capacitive RF MEMS switch or Tunable MEMS capacitor which may be made with a technological process based on dry etching of a silicon sacrificial layer and metals as suspended layers. The material of the suspended gate of prior art reports is polycrystalline silicon (polysilicon) and the sacrificial layers are silicon dioxide (SiO₂) or polymers. But the prior art never teaches to use silicon as sacrificial layer. In addition, most of the prior art processes use wet etching to release the suspended structures.

### SUMMARY OF THE INVENTION

It is therefore an object of the present invention to provide an improved process to manufacture MEMS devices.

Another object of the invention is to provide new MEMS devices architectures.

Those and other objects are accomplished with the process as defined in claim 1.

The thickness of the Si sacrificial layer may range from few tens of nm to few tens of μm.

The invention is particularly useful for the manufacture of a SG-MOFSET.

It is also particularly advantageous for the manufacture of an architecture using two metal layers that can be used both for capacitive RF switch and tunable MEMS capacitor. It includes two dielectric layers, each in contact with one of the metals. The upper dielectric is not mandatory and same structure can be used for same applications without this layer: It can however offer some advantages, at least in terms of extended stability of the structure. For the capacitive switch, a high-k dielectric layer may be added on the first metal layer to have a high capacitance ratio between ‘on’ and ‘off’ states. The final MEMS structure is released with dry etching of sacrificial silicon. It is worth noting that the overall process can be considered a surface micro-machining process for which the sacrificial layer is silicon and the body of the MEMS devices is a metal.

The invention may be also particularly useful for co-integration of MEMS devices with CMOS integrated circuits. In case of the use of polysilicon as sacrificial layer, SG-MOSFETs are realized in-CMOS process. In case of the use of amorphous silicon as sacrificial layer, the proposed process is low temperature (<450° C.) and can be used as post-CMOS process.

Some detailed examples of the invention will be discussed hereafter, with the support of the following figures:

### BRIEF DESCRIPTION OF THE DRAWINGS

FIG. 1: Cross sections of the suspended-gate MOSFET: (a) architecture on Silicon-On-Insulator, (b) architecture on silicon substrate and (c) architecture with the underneath silicon substrate etched. The gate is made of metal in all cases and its displacement is vertical.

FIG. 2: Upper view (Scanning Electron Microscopy images) of SG-MOSFETs with three different designs of the suspension metal arms.

FIG. 3: Design of a SG-MOSFET with lateral Hall contacts for silicon magnetic sensor with tunable sensitivity.

FIGS. 4.1-4.11: Detailed description of the SG-MOSFET technological process.

FIG. 5: Cross section and principle of the metal-metal tunable MEMS capacitor provided by the full-dry etching of sacrificial amorphous silicon: (a) architecture with one air-gap, (b) architecture with two air-gaps and separated electrostatic actuation, and (c) architecture with gradual air-gap.

FIG. 6: Cross section and principle of the metal-metal MEMS switch with high-k dielectric.

FIGS. 7.1-7.10: Detailed description of the tunable metal-metal MEMS capacitor technological process. On the left one air-gap, on the right two or more air-gaps (multi-air-gaps).

SG-MOSFET Architecture and Principle:

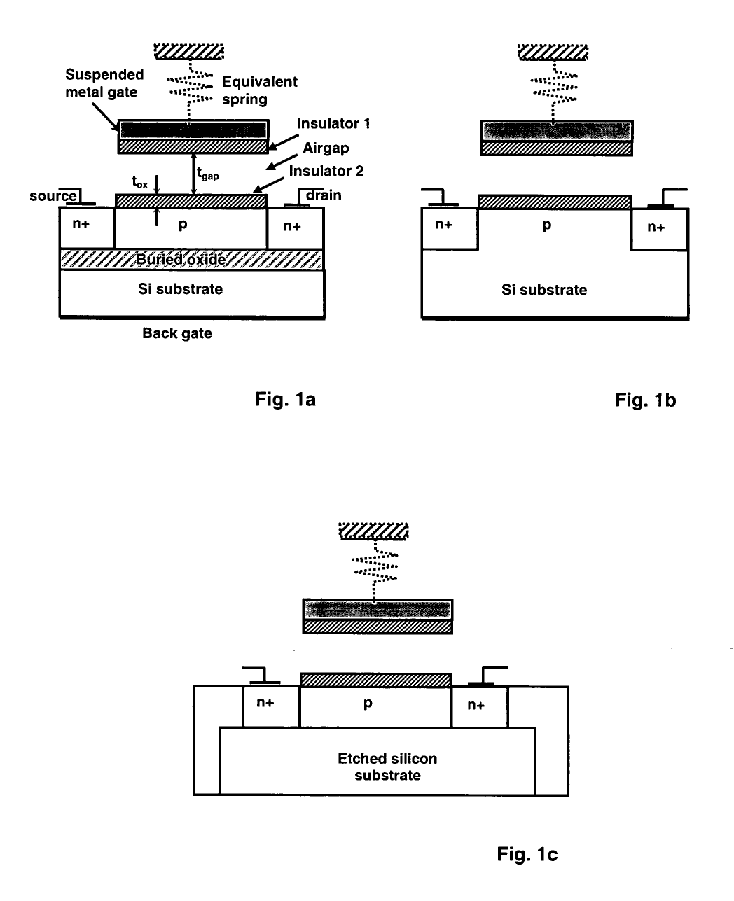

The cross section and the principle of the SG-MOSFET are depicted in FIGS. 1: it combines in a top-down architecture a suspended metal membrane used as movable gate with a MOS transistor. This architecture is nor a pure MEMS device nor a pure solid-state device, but a hybrid combination of both. When its gate voltage, V_{g}, is increased, the intrinsic gate-voltage, V_{gint}, which drives the MOS channel formation, is tuned according to a capacitor divider:

$${V}_{g int} = \frac{{V}_{g}}{1 + {C}_{gc int} / {C}_{gap}}$$

where C_{gcint}, C_{gap} are the intrinsic gate-to-channel capacitance of the underneath MOSFET and the air-gap capacitance, respectively. The membrane moves continuously downwards as long as the equilibrium is maintained between electrostatic and elastic forces:

$$\vert {F}_{elastic} \vert = kx = \frac{1}{2} \frac{{ɛ}_{air} {A ( {V}_{g} - {V}_{g int} )}^{2}}{{( {t}_{gap0} - x )}^{2}} = \vert {F}_{electr} \vert$$

where k is the equivalent elastic constant of the gate, x is the gate displacement, ,t_{gap0} the initial air-gap dimension and V_{gint} the intrinsic (or internal) gate voltage. When V_{g} equals the pull-in voltage, V_{PI}, unstable equilibrium is reached and the switch (suspended membrane) moves from the ‘off’ to the ‘on’ state.

Some unique characteristics of the SG-MOSFET are mentioned below:

(i) the dynamic threshold voltage: low in the ‘on’ state and high in the ‘off’ state, which is a key advantage for RF switch use because of a higher isolation in the ‘off’ state compared to the solid-state MOSFET;

(ii) the super-exponential dependence of Qᵢₙᵥ vs. V_{g} in the sub-threshold region, that can result in local sub-threshold slope better than the ideal limit of 60 mV/decade of any conventional MOSFET and the super-linear dependence of Qᵢₙᵥ vs. V_{g} in moderate and strong inversions;

(iii) the possibility to provide RF switches with capacitance ratios between ‘on’ and ‘off’ states better than 100;

(iv) the possibility to use the SG-MOSFET as tunable capacitor with tuning range better than any other similar MEMS capacitor.

(v) the possibility to use the SG-MOSFET as a capacitive or current switch (current could be driven when a voltage is applied on the drain when the source is grounded), both with better isolation in the off state (up position) compared with a solid state-device like a conventional MOSFET.

In reference [SG8] we have proposed the first unified analytical model of this device, including all regimes of operation.

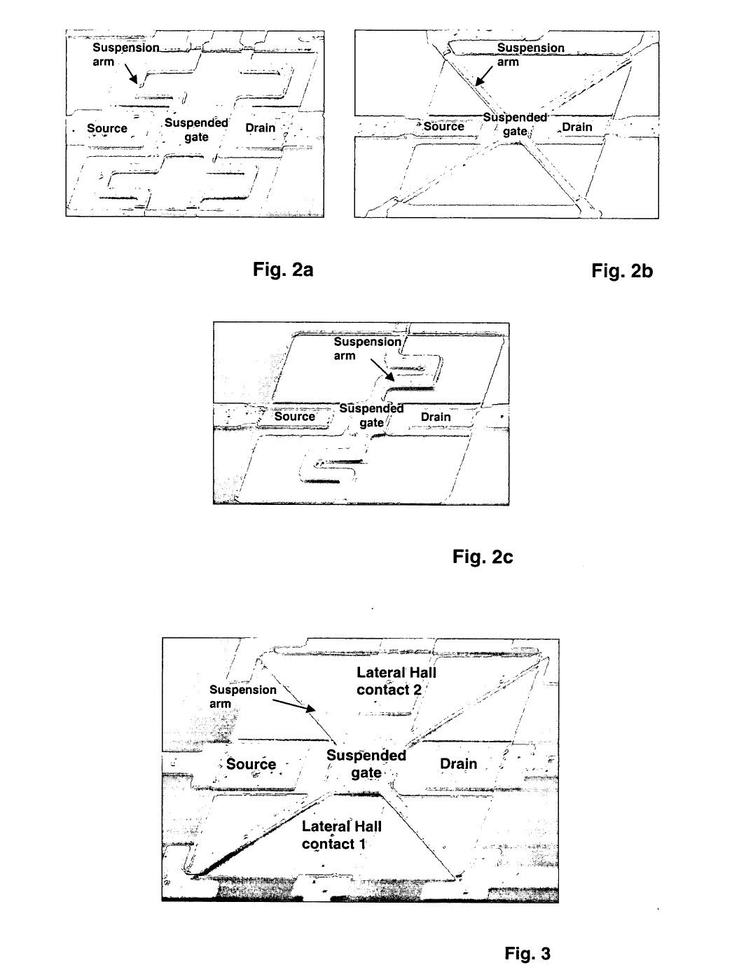

The key parameters of the SG-MOSFET architecture depicted in FIGS. 1 and 2 are: the thickness of the initial air-gap, the thickness of Insulator 1, the thickness of Insulator 2, the equivalent elastic constant k depending of the arm material and on their design, the surface of the metal suspended gate membrane.

FIGS. 2a, b, c present some typical designs of the suspension arms of the movable gate that directly impact on the equivalent k constant and then, on the value of the voltage needed to control the operation of the device: switching between ‘on’ and ‘off’ states or tuning of the gate capacitance. With the architecture and the technological process proposed herewith, the device operation can be achieved with voltages less that 5V, which makes it totally compatible with CMOS.

SG-MOSFET Applications:

The following applications of the SG-MOSFET are proposed:

1. SG-MOSFET as Radiofrequency (RF) MEMS capacitive (contactless) switch when the gate is electrostatically moved from ‘off’ (up) to ‘on’ (down) states;

2. SG-MOSFET as Radiofrequency (RF) MEMS tunable capacitor when the gate is electrostatically moved under equilibrium;

3. SG-MOSFET as MOSFET current switch when the gate is electrostatically switched between ‘off’ and ‘on’ states;

4. SG-MOSFET as integrated CMOS accelerometer wherein the acceleration is converted in vertical gate displacement and furthermore in variation of the drain current based on unique device;

5. SG-MOSFET as magnetic field sensor (MAGFET) with tunable sensitivity to a magnetic field perpendicular to the gate surface, accordingly to the displacement of the suspended gate under electrostatic forces.

Process for Manufacturing a SG-MOSFET:

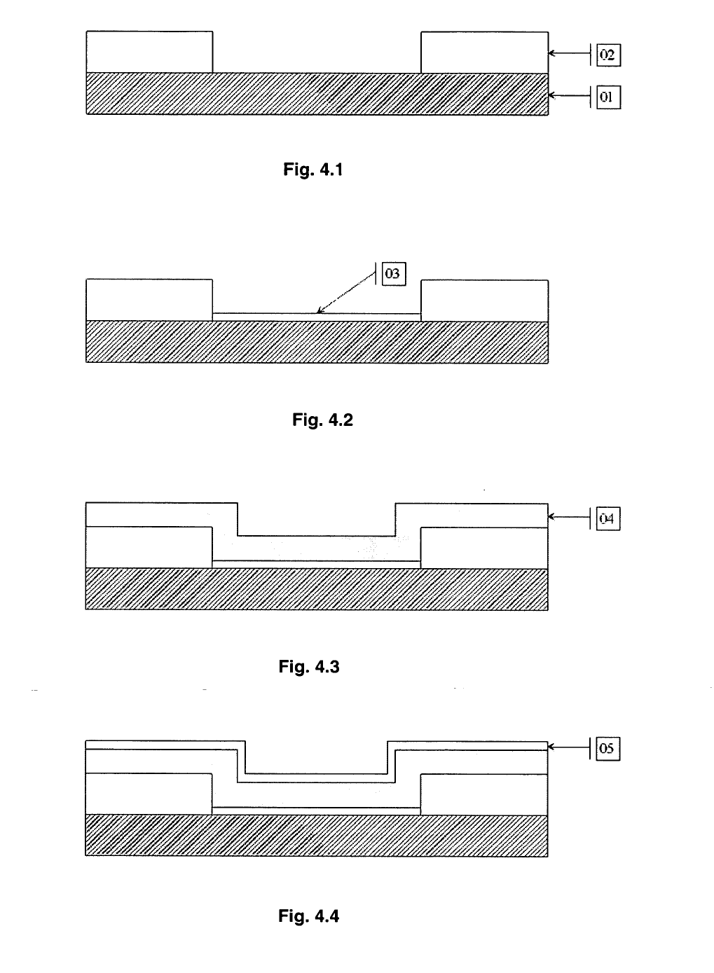

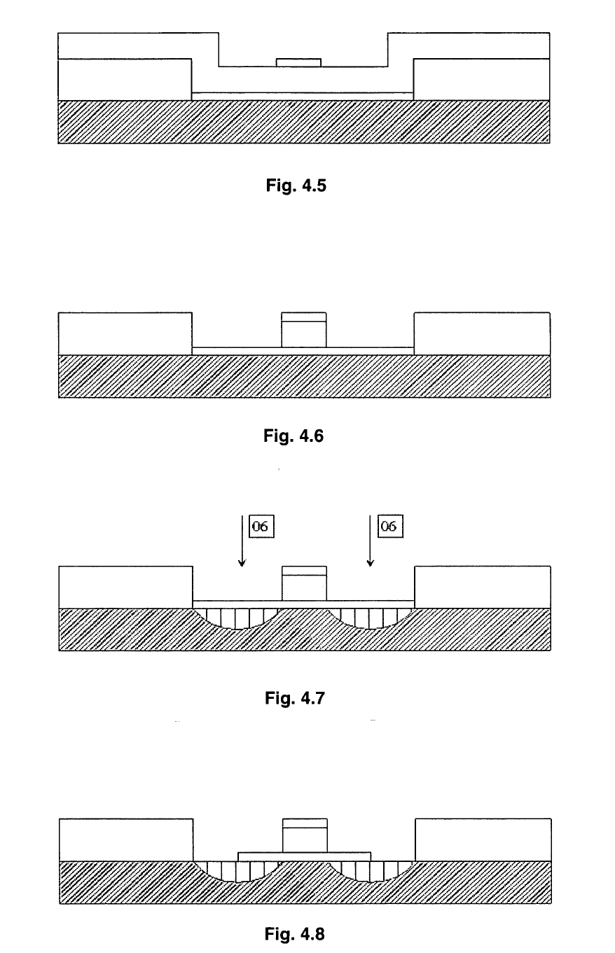

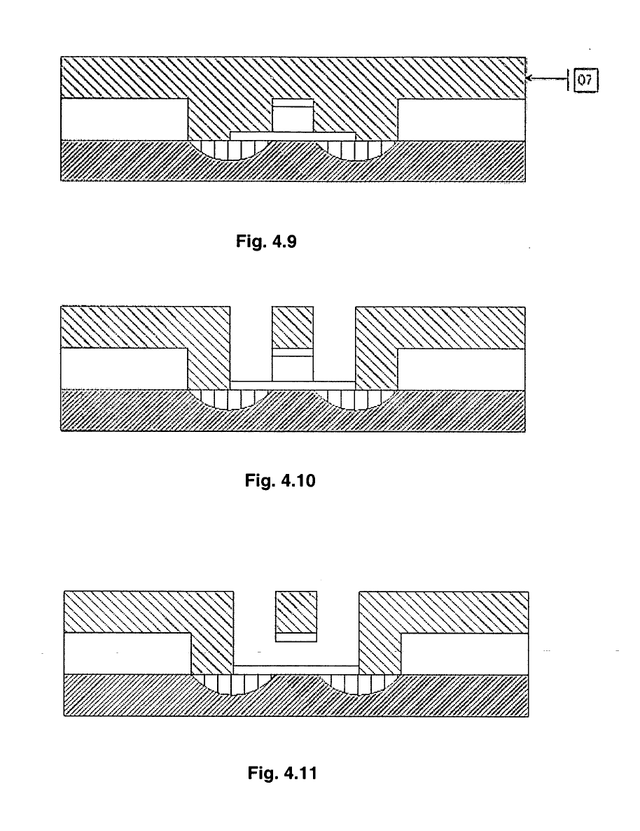

The fabrication of a SG-MOSFET in accordance with the present invention will be described with reference to FIGS. 4.1 to 4.11. The manufacturing process presented here is fully compatible with standard CMOS processes. A silicon substrate 01 is initially cleaned by conventional techniques and a field oxide layer 02, those thickness is about 500 nm, is grown in a wet atmosphere. Substrate 01 is <100> p-type silicon having a resistivity between 0.1-0.5 Ωcm. Alternatively, n-type Si substrate can also be used. Silicon-on-insulator (SOI) substrates are preferably used for RF applications to have high resistivity substrates. Using conventional photolithography techniques, the active device areas are formed by wet etching in a BHF (7:1) solution. The resulting structure is shown in FIG. 4.1.

The substrate 01 is then cleaned and a gate oxide layer 03 is thermally grown in a dry atmosphere as shown in FIG. 4.2. The thickness range is between 100 to 1000 A.

Next, as shown in FIG. 4.3, a silicon sacrificial layer 04 is deposited on the surface of the structure. The sacrificial layer 04 can be amorphous silicon or polysilicon. Amorphous silicon is deposited by different kind of techniques: physical vapor deposition techniques, i.e. evaporation, RF or DC sputtering, and chemical vapor deposition techniques, i.e. low pressure chemical vapor deposition (LPCVD) or plasma enhanced chemical vapor deposition (PECVD). Polysilicon is deposited by LPCVD but can also be obtained from amorphous silicon after thermal annealing. The thickness range is between 100 nm to 2 μm. As shown in FIG. 4.4, the sacrificial layer 04 is then covered by a SiO₂ diffusion barrier layer 05, those thickness is comprised between 1 nm to 100 nm. This layer prevents diffusion between the Si sacrificial layer 04 and the aluminum metal gate membrane 07. The barrier layer 05 can be obtained by dry oxidation of the Si sacrificial layer 04 or by deposition of a SiO₂ layer even by RF sputtering or by LPCVD (low temperature oxide (LTO): SiO₂, phosphosilicate glass (PSG) or borophosphosilicate glass (BPSG)). Using conventional photolithography techniques, the diffusion barrier layer 05 is patterned even by wet etching in BHF or HF solution or by dry etching technique based on CₓF_{y} RIE plasma process as shown in FIG. 4.5. The patterning of Si sacrificial layer 04 have to be anisotropic and highly selective on thin gate oxide 03. This can be performed by cryogenic SF₆/O₂ chemistry process or chlorine-based chemistry using inductively coupled plasma (ICP) reactors. The resulting structure is shown in FIG. 4.6.

Then, as shown in FIG. 4.7, source and drain regions 06 are formed in silicon substrate 01 using conventional self-aligned process. It should be noted that our Si sacrificial layer 04 plays the role of polysilicon gate in standard CMOS processes. Phosphorus or arsenic ions are implanted in case of p-type substrate to formed n-doped source and drain regions 06. For example, phosphorous ions are implanted at an energy of 25 keV and a dose of 2×10¹⁵ ions/cm². Alternatively, boron ions are implanted for n-type substrate to formed p-doped source and drain regions 06. The structure is then annealed in a nitrogen atmosphere, to avoid the oxidation of the silicon sacrificial layer 04 side walls, at 950° C., to repair damage to silicon substrate 01 due to implantation.

Next, as shown in FIG. 4.8, the gate oxide layer 03 is patterned by wet etching in a BHF solution to open contact holes to source and drain regions 06. Similarly, holes to contact the substrate 01 are opened.

The metal gate membrane layer 07 is then deposited on the surface of the structure as shown in FIG. 4.9. This layer also served as metal contacts to source and drain regions 06 and to substrate 01. For example, a 0.8 μm thick aluminum-silicon (with 1% silicon) is deposited by sputtering. Using conventional photolithography techniques, the aluminum gate membrane and the suspension arms are patterned by chlorine-based plasma chemistry or by wet etching in a standard ANP solution. The resulting structure is shown in FIG. 4.10.

The accelerometer application of SG-MOSFET needs a higher mass of the gate membrane in order to increase sensor sensitivity to acceleration without changing the rigidity of the suspension arms. This can be done by depositing a thicker metal layer 07. Then, the metal gate membrane is patterned by partial etching of the metal layer 07. After another photolithographic step, the suspension beams are formed.

Next, the diffusion barrier layer 05 is patterned even by dry etching technique based on CₓF_{y} RIE plasma process or by wet etching in NH₄F solution, with high selectivity to aluminum, to have an access to the silicon sacrificial layer 04.

Finally, the suspended metal gate membranes are released by dry etching in a fluorine-based chemistry with high selectivity to SiO₂ thin gate oxide layer 03 and metal layer 07, as shown in FIG. 4.11.

Metal-Metal RF MEMS Switch and Tunable Capacitor Architecture and Principle:

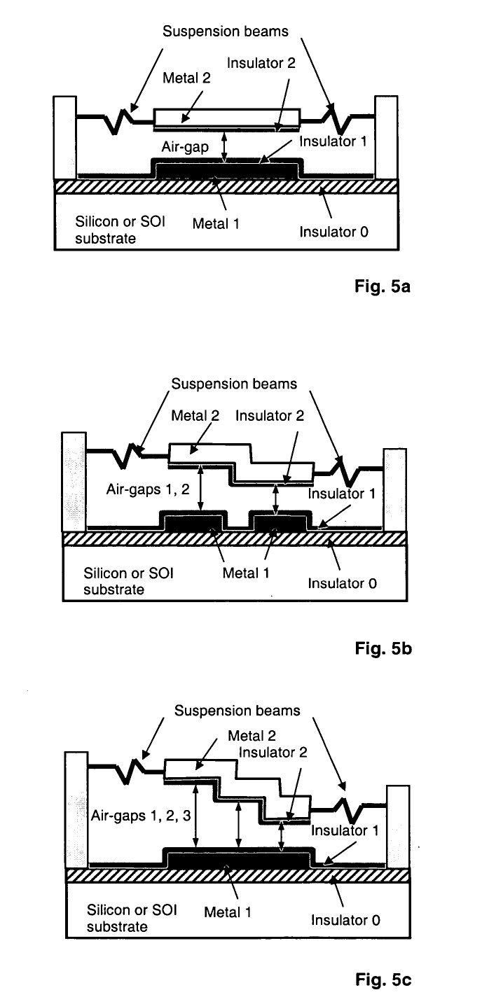

The cross section of the MEMS tunable capacitor proposed device is described in FIGS. 5: It uses two metal layers, capped with two insulators (Insulators 1 and 2) separated by different air-gaps. Metal 1 is deposited on top of another insulator called Insulator 0 that can be SiO₂. The movable metal membrane is defined by Metal 2 and its vertical displacement is controlled by the applied voltage.

FIG. 5a shows a simple air-gap tunable capacitor which has a capacitance tuning range limited by the pull-in effect.

FIG. 5b presents an architecture with two air-gaps (Air-gap 1 and Air-gap 2, Air-gap 1 is designed larger than Air-gap 2) wherein the capacitance tuning range is significantly enlarged because the equilibrium region between electrostatic and elastic forces is enlarged.

The difference with respect to other publications that proposes also the use of two air-gaps is that, our architecture uses two insulator layers over the metals, resulting in different characteristics, and the releasing process is completely different, with amorphous silicon as sacrificial layer. Moreover much more aggressively scaled dimensions in terms of air-gaps can be addressed with our structure. Advantages of better yield and fully compatible CMOS process can be mentioned. Also, by the proper design of the suspension arms (with meanders), a low voltage, CMOS-compatible, operation can be achieved for this structure. Another advantage of our technological process is that it is compatible for multi-air-gaps and gradual air-gaps (see FIG. 5c) architectures which lead to increase properties compared with two-air-gaps structures.

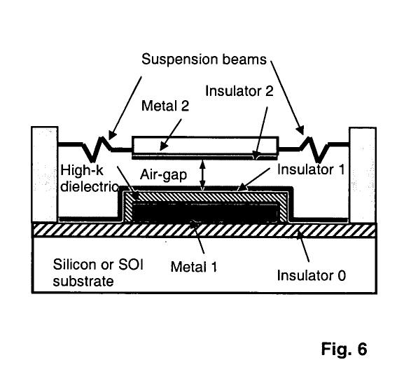

This technological process can be used for both MEMS RF capacitive switch and tunable capacitor applications. For the capacitive switch, we add a high-k dielectric layer between Metal 1 and Insulator 1 to get a high capacitance ratios between ‘on’ and ‘off’ states (see FIG. 6).

Metal-Metal MEMS Device Applications:

The following applications of the metal-metal MEMS device architecture are proposed:

1. Radiofrequency (RF) MEMS capacitive (contactless) switch when the gate is electrostatically moved from ‘off’ (up) to ‘on’ (down) states;

2. Radiofrequency (RF) MEMS tunable capacitor when the gate is electrostatically moved under equilibrium;

3. Integrated CMOS accelerometer wherein the acceleration is converted in vertical displacement of the membrane and furthermore in variation of the capacitance.

Process for Manufacturing a Metal-Metal MEMS Switch or a Tunable Capacitor:

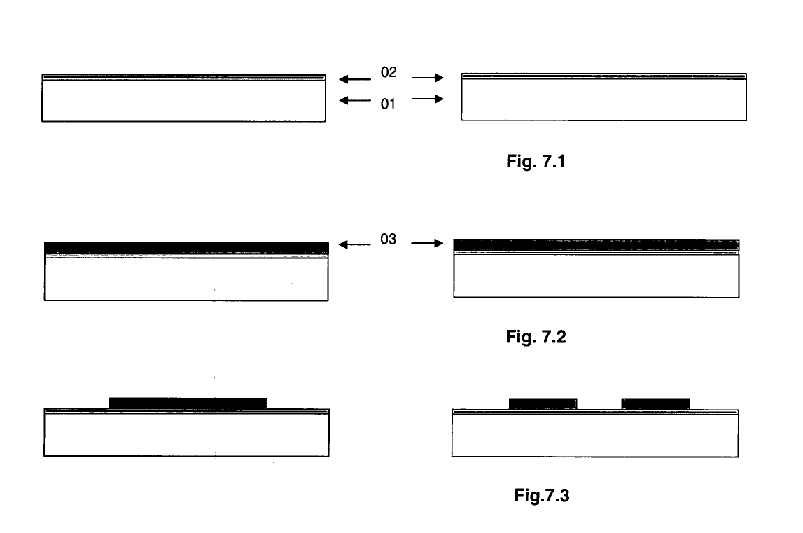

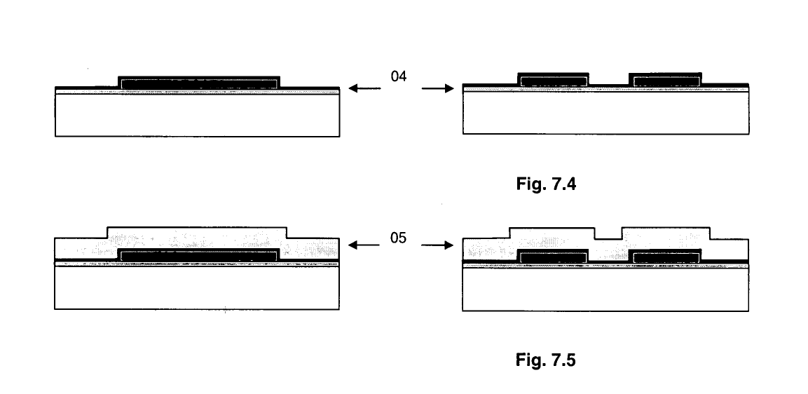

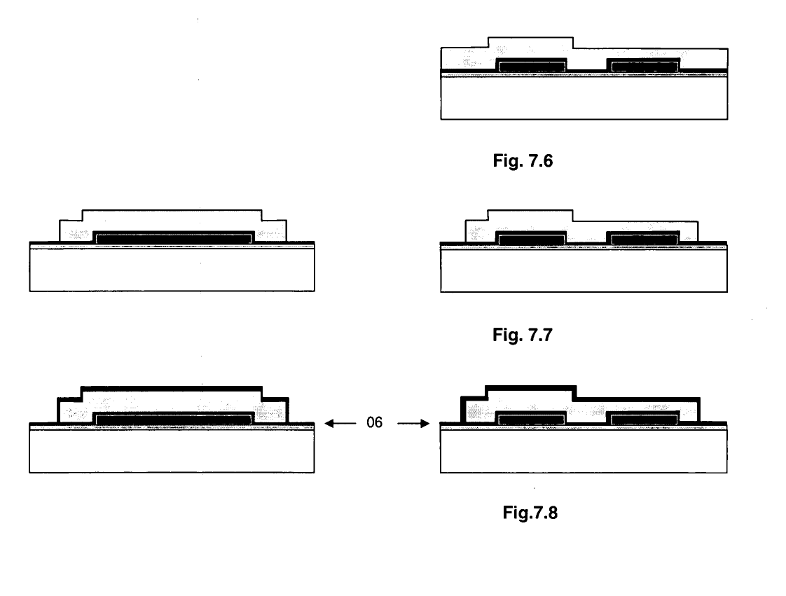

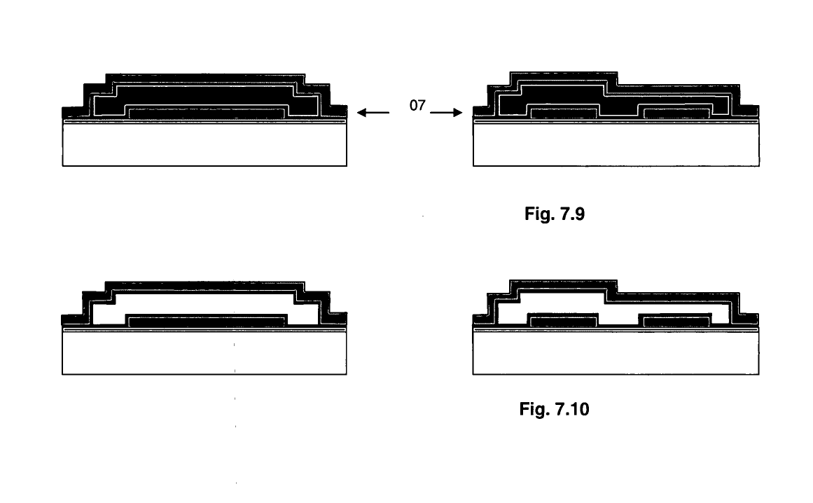

The fabrication of metal-metal tunable capacitors and switches in accordance with the present invention will be described with reference to FIGS. 7.1 to 7.10. The method of fabrication presented here is fully compatible with CMOS post-processing. A silicon substrate 01 is initially cleaned by conventional techniques and a silicon dioxide layer 02 is grown in a wet atmosphere as shown in FIG. 7.1. The thickness range is between 0.2 to 2 μm. A low temperature oxide (LTO) deposited by LPCVD can replace the wet oxidation. Silicon-on-insulator (SOI) substrates are preferably used for RF applications to have high resistivity substrates.

Then, the first metal layer 03 is deposited on the surface as shown in FIG. 7.2. A 1 μm thick aluminum-silicon layer (with 1% silicon) is sputtered. Using conventional photolithography techniques, the aluminum base electrodes and the contact pads are patterned by chlorine-based plasma chemistry or by wet etching in a standard ANP solution as shown in FIG. 7.3.

For the fabrication of capacitive switches, a dielectric layer with high dielectric constant (high-k dielectric) is deposited and patterned by dry plasma chemistry on the first metal layer 03. The high-k dielectric can be sputtered or PECVD silicon nitride or sputtered TiO₂.

As shown in FIG. 7.4, the structures are then covered by a SiO₂ diffusion barrier layer 04, the thickness of which is comprised between 10 to 100 nm. This layer will prevent diffusion between the silicon sacrificial layer 05 and the aluminum base electrodes. The barrier layer 04 can be obtained by deposition of a SiO₂ layer even by RF sputtering or by LPCVD (low temperature oxide (LTO): SiO₂, phosphosilicate glass (PSG).

Next, as shown in FIG. 7.5, an amorphous silicon sacrificial layer 05 is deposited on the surface of the structure. Amorphous silicon is deposited by different kind of techniques: physical vapor deposition techniques, i.e. evaporation, RF or DC sputtering, and plasma enhanced chemical vapor deposition (PECVD). The thickness range is between 100 nm to 3 μm.

The patterning of amorphous silicon sacrificial layer 05 is performed by chlorine- or fluorine-based chemistry process using inductively coupled plasma (ICP) reactors. Several photolithographic steps are needed to provide the three-dimensional membrane shape and multi-air-gaps architecture. The first steps consist in thinning the silicon sacrificial layer 05 to define the different air-gaps as shown in FIG. 7.6. The second step consists in passing through the silicon sacrificial layer 05 to prepare the mechanical anchors to the substrate 01 for the suspended membranes. The resulting structure is shown in FIG. 7.7.

As shown in FIG. 7.8, the patterned sacrificial layer 05 is then covered by a SiO₂ diffusion barrier layer 06, those thickness is comprised between 10 to 100 nm. The second metal layer 07 is then deposited on the surface of the structure. A 1 μm thick aluminum-silicon (with 1% silicon) is sputtered. Using conventional photolithography techniques, the aluminum membrane and the suspension beams are patterned even by chlorine-based plasma chemistry or by wet etching in a standard ANP solution. The resulting structure is shown in FIG. 7.9. Next, the diffusion barrier layer 06 is patterned by dry etching technique based on CₓF_{y} RIE plasma process to have an access to silicon sacrificial layer 05.

Then, the suspended metal membranes are released by dry etching of the silicon sacrificial layer 05 in a fluorine-based chemistry with a high selectivity to SiO₂ and aluminum as shown in FIG. 7.10. Finally, the diffusion barrier layer 04 on electric contacts is removed by anisotropic CₓF_{y} RIE plasma process.

1. Process for manufacturing a Micro-Electro-Mechanical-System (MEMS) comprising the use of a sacrificial layer characterized by the fact that the sacrificial layer is made of silicon.

2. Process according to the claim 1 wherein the silicon sacrificial layer is removed by plasma etching with fluorine-based chemistry.

3. Process according to claim 1 wherein the silicon sacrificial layer is removed by xenon difluoride (XeF2) or bromine trifluoride (BrF3) etching.

4. Process according to claim 1 wherein the silicon is in polycrystalline form.

5. Process according to claim 1 wherein the silicon is in amorphous form.

6. Process according to claim 1 characterized by the fact that it is used in surface micromachining.

7. Process according to claim 1 characterized by the fact that it is used for the manufacture of a MEMS containing a suspended metal layer.

8. MEMS device architecture obtained according to the process as defined in claim 1.

9. MEMS device according to claim 8 to be fabricated on silicon, silicon-on-insulator substrates and on silicon with the underneath substrate etched.

10. MEMS device according to claim 8 characterized by the fact that it comprises a suspended metal gate.

11. MEMS device according to claim 10 characterized by the fact that it is a suspended gate MOSFET.

12. MEMS device according to claim 10 wherein said metal is aluminum, AlSi, AlSiCu, copper, gold, tungsten, platinum, titanium or a combination of these metals.

13. MEMS device architecture obtained according to the process as defined in claim 1 and using two metal levels, one fixed and one movable, called membrane, both capped with one insulator, with variable air-gaps and an underlying insulator deposited on a semiconductor substrate.

14. MEMS device according to claim 13 characterized by the fact that it comprises a high-k dielectric made of TiO2.

15. Use of the device of claim 10 as radiofrequency capacitive switch.

16. Use of the device of claim 10 as current switch.

17. Use of the device of claim 10 as radiofrequency tuneable capacitor.

18. Use of the device of claim 10 as magnetic field sensor.

19. Use of the device of claim 10 as accelerometer.

20. Use of the device of claim 10 as pressure sensor.
